(19) United States
(12) Patent Application Publication
(10) Pub. No.: US 2024/0146282 A1
(43) Pub. Date: May 2, 2024

(54) RESONATOR DEVICE

(71) Applicant: SEIKO EPSON CORPORATION, Tokyo (JP)

(72) Inventor: Yusuke Matsuzawa, Chino-shi (JP)

(21) Appl. No.: 18/495,113

(22) Filed: Oct. 26, 2023

(30) Foreign Application Priority Data
Oct. 28, 2022 (JP) 2022-173078

(51) Int. Cl. H03H 9/10; H03H 9/13; H03H 9/19

(52) U.S. Cl. CPC H03H 9/10; H03H 9/132; H03H 9/19

(57) ABSTRACT

A resonator device includes an element substrate provided with a resonator element having a first excitation electrode arranged on one surface and a second excitation electrode arranged on another surface, and a frame surrounding the resonator element, a lid substrate bonded to one surface of the frame, a base substrate bonded to another surface of the frame, and a semiconductor element including an oscillation circuit electrically coupled to the resonator element, wherein the frame, the lid substrate, and the base substrate form a cavity for housing the resonator element and the semiconductor element, the base substrate includes a first wiring line which is arranged on a surface faced to the second excitation electrode, and electrically couples the first excitation electrode and the semiconductor element to each other, and the first wiring line is arranged at a position which fails to overlap the second excitation electrode in a plan view.

The present application is based on, and claims priority from JP Application Serial Number 2022-173078, filed Oct. 28, 2022, the disclosure of which is hereby incorporated by reference herein in its entirety.

### BACKGROUND

### 1. Technical Field

The present disclosure relates to a resonator device.

### 2. Related Art

In JP-A-2012-147148 (Document 1), there is disclosed a configuration of a piezoelectric device provided with a piezoelectric resonator unit which vibrates with a pair of excitation electrodes formed on both principal surfaces, a lid and a base which airtightly seal the piezoelectric resonator unit, and an integrated circuit arranged at the piezoelectric resonator unit side of the base.

Here, when the excitation electrode closer to the integrated circuit is referred to as a first excitation electrode, and the excitation electrode farther from the integrated circuit is referred to as a second excitation electrode, a wiring line electrically coupled to the second excitation electrode out of wiring lines coupled to the integrated circuit from the pair of excitation electrodes is arranged so as to be laid around a position faced to the first excitation electrode.

However, in the technology described in Document 1, the wiring line coupled to the second excitation electrode is arranged at a position faced to the first excitation electrode, namely arranged so as to overlap the first excitation electrode in a plan view, and a potential difference occurs between the wiring line and the first excitation electrode, and therefore, the parasitic capacitance increases, and there is a possibility that electrical characteristics of the oscillator deteriorate.

### SUMMARY

A resonator device includes an element substrate having a resonator element which has a first excitation electrode arranged on one surface and a second excitation electrode arranged on another surface, and a frame surrounding the resonator element, a first substrate bonded to one surface of the frame, a second substrate bonded to another surface of the frame, and a semiconductor element including an oscillation circuit electrically coupled to the resonator element, wherein the frame, the first substrate, and the second substrate form a cavity configured to house the resonator element and the semiconductor element, the second substrate includes a first wiring line which is arranged on a surface faced to the second excitation electrode, and which is configured to electrically couple the first excitation electrode and the semiconductor element to each other, and the first wiring line is arranged at a position which fails to overlap the second excitation electrode in a plan view.

### BRIEF DESCRIPTION OF THE DRAWINGS

FIG. 1 is a plan view showing a configuration of the resonator device.

FIG. 2 is a cross-sectional view of the resonator device along the line A-A shown in FIG. 1.

FIG. 3 is a diagram for explaining a cutting angle of a quartz crystal.

FIG. 4 is a plan view showing a configuration of an element substrate of the resonator device.

FIG. 5 is a plan view showing a configuration of a lid substrate as a first substrate of the resonator device.

FIG. 6 is a plan view showing a configuration of a base substrate as a second substrate of the resonator device.

FIG. 7 is a plan view showing a configuration of a resonator device according to a modified example.

FIG. 8 is a cross-sectional view showing the configuration of the resonator device according to the modified example.

FIG. 9 is a plan view showing a configuration of an element substrate of the resonator device according to the modified example.

FIG. 10 is a plan view showing a configuration of a base substrate of the resonator device according to the modified example.

### DESCRIPTION OF EMBODIMENTS

In each of the drawings described below, the description will be presented defining three axes perpendicular to each other as an X axis, a Y′ axis, and a Z′ axis. The X axis, the Y′ axis, and the Z′ axis show the crystal axes of the quartz crystal as described later. Further, a direction along the X axis is referred to as an “X direction,” a direction along the Y′ axis is referred to as a “Y′ direction,” and a direction along the Z′ axis is referred to as a “Z′ direction,” and an arrow direction is defined as a “+” direction while a direction opposite to the “+” direction is defined as a “−” direction. It should be noted that the +Y′ direction is referred to as an “upper side” or “above” or an “obverse side” in some cases, and the −Y′ direction is referred to as a “lower side” or “below” or a “reverse side” in some cases, and a view from the +Y′ direction or the −Y′ direction is also referred to as a plan view or “planar.” Further, the description will be presented defining a surface at a “+” side in the Y′ direction as an “upper surface” or an “obverse side,” and a surface at a “−” side in the Y′ direction which is an opposite side thereto as a “lower surface” or a “reverse surface.”

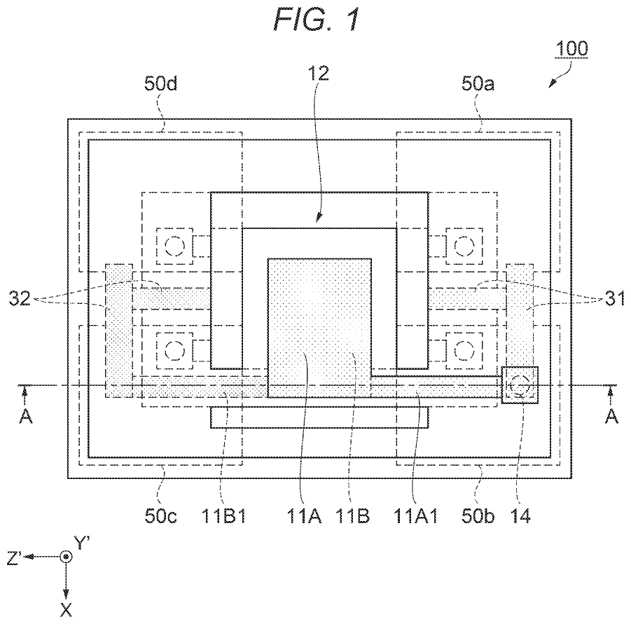

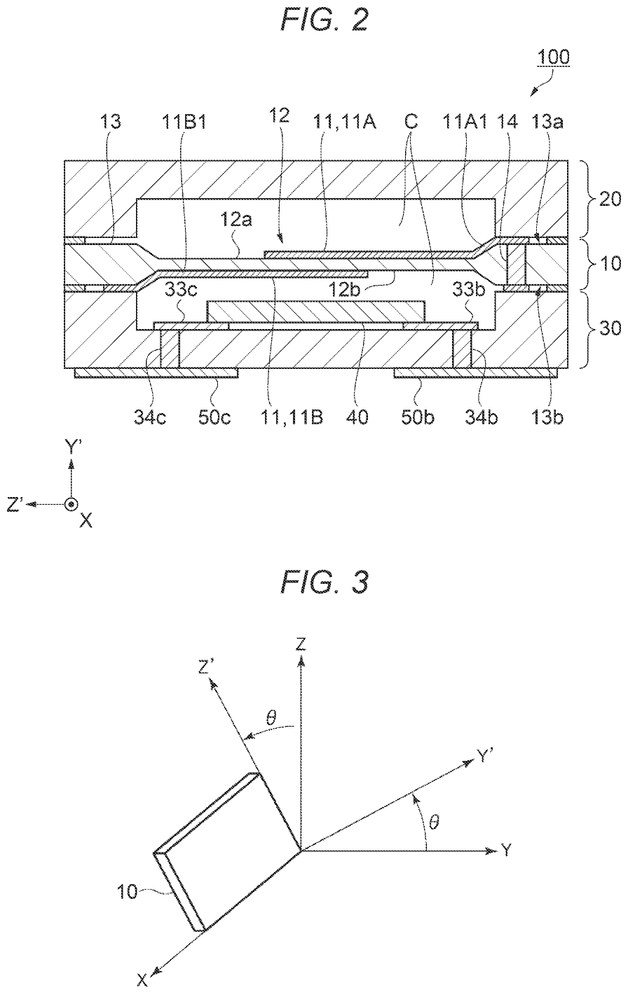

First, a configuration of a resonator device 100 will be described with reference to FIG. 1 and FIG. 2.

As shown in FIG. 1 and FIG. 2, the resonator device 100 is provided with an element substrate 10 having a pair of excitation electrodes 11, a lid substrate 20 as a first substrate arranged at one side of the element substrate 10, a base substrate 30 as a second substrate arranged at the other side of the element substrate 10, and a semiconductor element 40 arranged on the base substrate 30.

Specifically, the element substrate 10 is formed of the quartz crystal, and is provided with a resonator element 12 having a first excitation electrode 11A arranged on one surface 12a and a second excitation electrode 11B arranged on the other surface 12b, and a frame 13 surrounding the resonator element 12. The element substrate 10 in the present embodiment is formed of an AT-cut quartz crystal substrate.

The AT cut quartz crystal substrate will briefly be described. The element substrate 10 has crystal axes X, Y, and Z perpendicular to each other. It should be noted that the X axis, the Y axis, and the Z axis are called an electrical axis, a mechanical axis, and an optical axis, respectively. Further, as shown in FIG. 3, the element substrate 10 is a “rotated Y-cut quartz crystal substrate” carved out along a plane obtained by rotating the X-Z plane around the X axis as much as a predetermined angle θ, and the substrate which is carved out along a plane rotated as much as θ=35° 15′ is referred to as an “AT-cut quartz crystal substrate.” The Y axis and the Z axis rotated around the X axis in accordance with the angle θ are hereinafter referred to as the Y′ axis and the Z′ axis, respectively. In other words, the element substrate 10 has thickness in the Y′-axis direction, and a spread in the X-Z′ plane direction.

The lid substrate 20 is bonded to one surface 13a of the frame 13 of the element substrate 10. The base substrate 30 is bonded to the other surface 13b of the frame 13 of the element substrate 10. The element substrate 10, the lid substrate 20, and the base substrate 30 are bonded to each other with, for example, Au (gold)-Au (gold) surface activated bonding. The semiconductor element 40 includes an oscillation circuit, and is electrically coupled to the resonator element 12.

The frame 13 of the element substrate 10, the lid substrate 20, and the base substrate 30 are combined with each other to thereby form a cavity C for housing the resonator element 12 and the semiconductor element 40. An inside of the cavity C is set in, for example, a reduced-pressure state, and preferably a state more approximate to a vacuum state. Thus, the vibration characteristics of the resonator device 100 are improved.

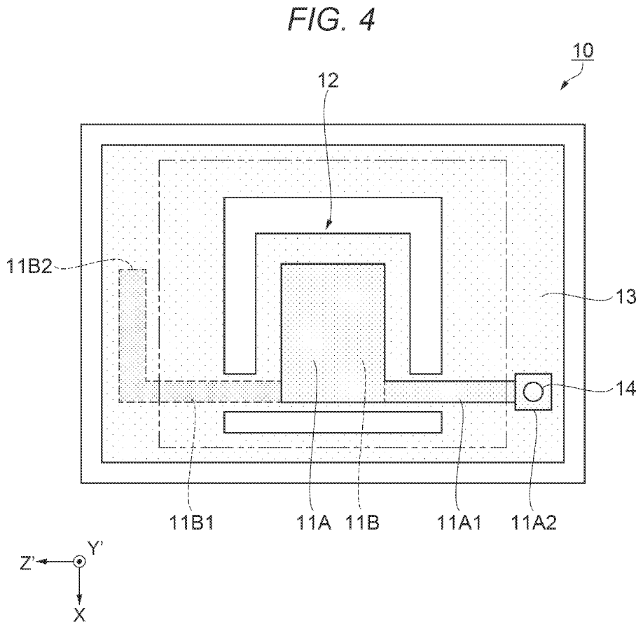

Then, the configuration of the element substrate 10, the lid substrate 20, and the base substrate 30 will be specifically described with reference to FIG. 4 through FIG. 6.

As shown in FIG. 4, the element substrate 10 has the frame 13 having a frame shape, and the resonator element 12 arranged inside the frame 13. The resonator element 12 is, for example, an AT-cut quartz crystal substrate functioning in a thickness-shear vibration mode, and has a third-order frequency-temperature characteristic. It should be noted that the element substrate 10 is not limited to the AT-cut quartz crystal substrate, and can be a quartz crystal substrate of other cutting angles such as Z-cut, SC-cut, ST-cut, and BT-cut.

Further, as shown in FIG. 4, in the element substrate 10, there are arranged a first extraction electrode 11A1 for extracting the first excitation electrode 11A to a position of the frame 13, and a second extraction electrode 11B1 for extracting the second excitation electrode 11B to the position of the frame 13.

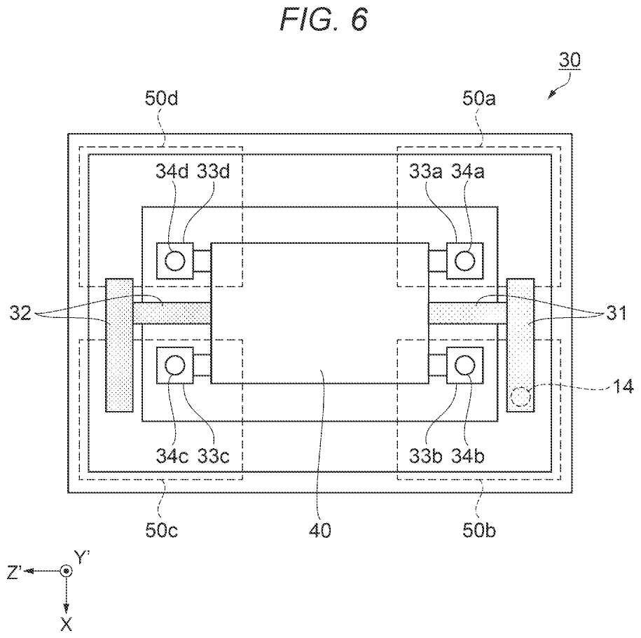

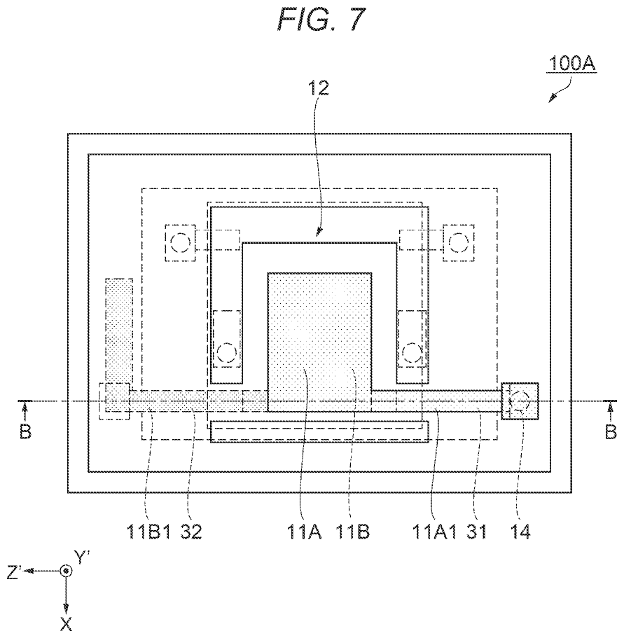

In the element substrate 10, at a position overlapping an end portion 11A2 of the first extraction electrode 11A1, there is disposed a through electrode 14 penetrating the frame 13. The through electrode 14 is electrically coupled to a first wiring line 31 (see FIG. 6) arranged on the base substrate 30. In other words, the first excitation electrode 11A is electrically coupled to the first wiring line 31. The first wiring line 31 is electrically coupled to the semiconductor element 40.

In the element substrate 10, at a position overlapping the second extraction electrode 11B1 and an end portion 11B2, a second wiring line 32 (see FIG. 6) arranged on the base substrate 30 is directly and electrically coupled without disposing a through electrode.

The constituent material of the excitation electrodes 11A, 11B and the extraction electrodes 11A1, 11B1 is not particularly limited, and it is possible to use a metal material such as gold (Au), silver (Ag), platinum (Pt), palladium (Pd), iridium (Ir), copper (Cu), aluminum (Al), nickel (Ni), chromium (Cr), titanium (Ti), or tungsten (W), or an alloy including any of these metal materials. It should be noted that the first wiring line 31 and the second wiring line 32 are formed of substantially the same material as the material described above.

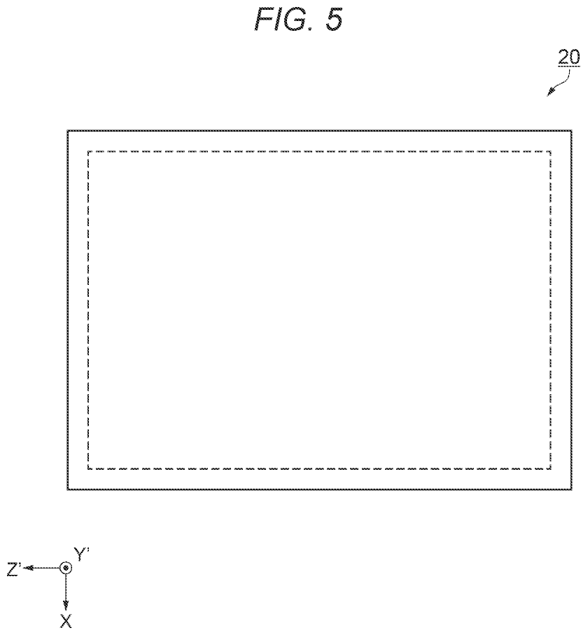

As shown in FIG. 5, the lid substrate 20 is formed of a quartz crystal or a glass substrate, and is provided with a recessed part (see FIG. 2) for forming the cavity C at the reverse surface side (the −Y′-axis direction).

As shown in FIG. 6, on the base substrate 30, there are arranged the semiconductor element 40, the first wiring line 31, and the second wiring line 32 as described above. Further, on the base substrate 30, there are arranged terminals 33a, 33b, 33c, and 33d electrically coupled to the semiconductor element 40.

The terminals 33a, 33b, 33c, and 33d are electrically coupled respectively to through electrodes 34a, 34b, 34c, and 34d penetrating the base substrate 30. The through electrodes 34a, 34b, 34c, and 34d are electrically coupled respectively to external electrodes 50a, 50b, 50c, and 50d arranged on the reverse surface of the base substrate 30.

As described above, the first wiring line 31 coupled to the first excitation electrode 11A is arranged at a position which does not overlap the second excitation electrode 11B and the second extraction electrode 11B1 in the plan view. In other words, since the second excitation electrode 11B and the first wiring line 31 different in potential are arranged so as not to overlap each other as shown in FIG. 1, it is possible to prevent a parasitic capacitance from being generated between the first wiring line 31 and the second excitation electrode 11B. Further, since the first wiring line 31 and the second extraction electrode 11B1 different in potential are arranged so as not to overlap each other, it is possible to prevent a parasitic capacitance from being generated between the first wiring line 31 and the second extraction electrode 11B1. Therefore, it is possible to suppress the deterioration of the electrical characteristics of the oscillation circuit.

Meanwhile, the second wiring line 32 coupled to the second excitation electrode 11B is arranged at a position which does not overlap the first excitation electrode 11A and the first extraction electrode 11A1 in the plan view. In other words, since the first excitation electrode 11A and the second wiring line 32 different in potential are arranged so as not to overlap each other as shown in FIG. 1, it is possible to prevent a parasitic capacitance from being generated between the second wiring line 32 and the first excitation electrode 11A. Further, since the second wiring line 32 and the first extraction electrode 11A1 different in potential are arranged so as not to overlap each other, it is possible to prevent a parasitic capacitance from being generated between the second wiring line 32 and the first extraction electrode 11A1. Therefore, it is possible to suppress the deterioration of the electrical characteristics of the oscillation circuit.

Further, the first extraction electrode 11A1 and the first wiring line 31 are extracted toward the −Z′ direction as one side of the base substrate 30, namely the resonator device 100. The second extraction electrode 11B1 and the second wiring line 32 are extracted toward the +Z′ direction as the other side of the base substrate 30, namely the resonator device 100.

As described above, since the first wiring line 31 and the second wiring line 32 extend in respective directions of getting away from the pair of excitation electrodes 11, it is possible to arrange the extraction electrodes 11A1, 11B1, and the wiring lines 31, 32 so as not to overlap each other in the plan view. Therefore, it is possible to prevent the generation of the parasitic capacitance due to the wiring lines different in potential overlapping each other in the plan view.

As described hereinabove, the resonator device 100 according to the present embodiment has the element substrate 10 provided with the resonator element 12 having the first excitation electrode 11A arranged on the one surface 12a and the second excitation electrode 11B arranged on the other surface 12b, and the frame 13 surrounding the resonator element 12, the lid substrate 20 as the first substrate bonded to the one surface 12a of the frame 13, the base substrate 30 as the second substrate bonded to the other surface 12b of the frame 13, and the semiconductor element 40 including the oscillation circuit electrically coupled to the resonator element 12, the frame 13, the lid substrate 20, and the base substrate 30 form the cavity C for housing the resonator element 12 and the semiconductor element 40, the base substrate 30 includes the first wiring line 31 which is arranged on the surface faced to the second excitation electrode 11B, and electrically couples the first excitation electrode 11A and the semiconductor element 40 to each other, and the first wiring line 31 is arranged at the position which does not overlap the second excitation electrode 11B in the plan view.

According to this configuration, since the first wiring line 31 and the second excitation electrode 11B different in potential are arranged so as not to overlap each other in the plan view, it is possible to prevent the parasitic capacitance from being generated between the first wiring line 31 and the second excitation electrode 11B. Therefore, it is possible to suppress the deterioration of the electrical characteristics of the oscillation circuit.

Further, in the resonator device 100 according to the present embodiment, it is preferable that the resonator element 12 is provided with the second extraction electrode 11B1 coupled to the second excitation electrode 11B, and the first wiring line 31 is arranged at the position which does not overlap the second excitation electrode 11B and the second extraction electrode 11B1 in the plan view. According to this configuration, since the first wiring line 31, and the second excitation electrode 11B and the second extraction electrode 11B1 which are different in potential from the first wiring line 31 are arranged so as not to overlap each other in the plan view, it is possible to prevent the parasitic capacitance from being generated between the first wiring line 31 and the second excitation electrode 11B, and between the first wiring line 31 and the second extraction electrode 11B1.

Further, in the resonator device 100 according to the present embodiment, it is preferable that the base substrate 30 includes the second wiring line 32 which is arranged on the surface faced to the second excitation electrode 11B, and electrically couples the second excitation electrode 11B and the semiconductor element 40 to each other, the first wiring line 31 is arranged at the one side of the base substrate 30, and the second wiring line 32 is arranged at the other side as the opposite direction to the one side of the base substrate 30. According to this configuration, since the first wiring line 31 and the second wiring line 32 are arranged separately from each other in the base substrate 30, it is possible to prevent the parasitic capacitance from being generated between the wiring lines different in potential from each other.

A modified example of the embodiment described above will hereinafter be described.

As described above, arranging the first extraction electrode 11A1 and the first wiring line 31 the same in potential so as not to overlap each other in the plan view is not a limitation, and it is possible to arrange the first extraction electrode 11A1 and the first wiring line 31 so as to overlap each other in the plan view as shown in FIG. 7 through FIG. 10 as long as the potentials are the same.

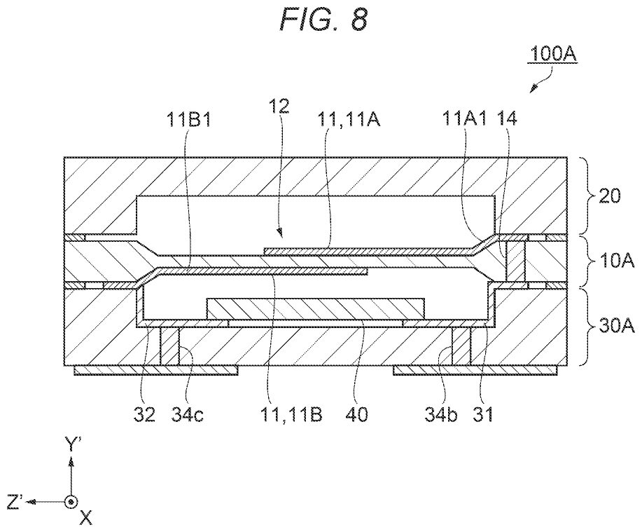

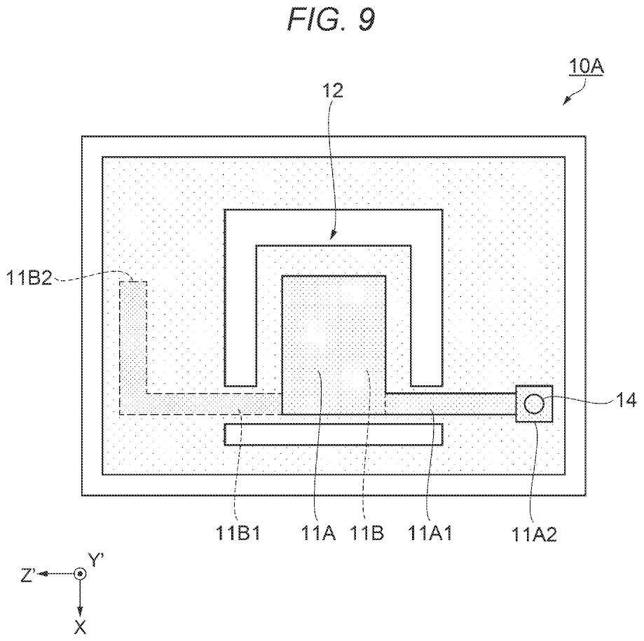

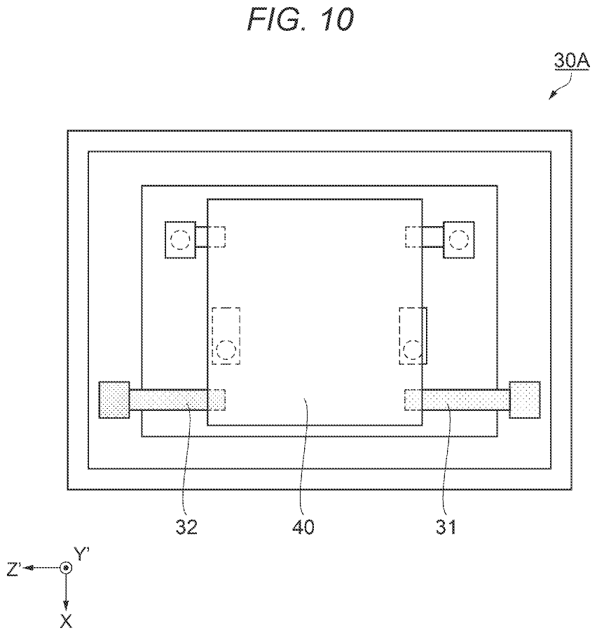

Specifically, as shown in FIG. 7, FIG. 9, and FIG. 10, the first extraction electrode 11A1 provided to the element substrate 10A is arranged so as to overlap the first wiring line 31 provided to the base substrate 30 in the plan view. As shown in FIG. 8, the first extraction electrode 11A1 and the first wiring line 31 are electrically coupled to each other with the through electrode 14 provided to the element substrate 10A. In other words, the first extraction electrode 11A1 and the first wiring line 31 the same in potential are arranged so as to overlap each other in the plan view.

As described above, since the first extraction electrode 11A1 and the first wiring line 31 are the same in potential, it is possible to prevent the parasitic capacitance from being generated even when the first extraction electrode and the first wiring line are arranged so as to overlap each other in the plan view. Further, on a base substrate 30A, it is possible to arrange the first wiring line 31 in a space limited in area.

Further, as shown in FIG. 7, FIG. 9, and FIG. 10, the second extraction electrode 11B1 provided to the element substrate 10A is arranged so as to overlap the second wiring line 32 provided to the base substrate 30A in the plan view. As shown in FIG. 8, the second extraction electrode 11B1 and the second wiring line 32 are directly and electrically coupled to each other without disposing the through electrode. In other words, the second extraction electrode 11B1 and the second wiring line 32 the same in potential are arranged so as to overlap each other in the plan view.

As described above, since the second extraction electrode 11B1 and the second wiring line 32 are the same in potential, it is possible to prevent the parasitic capacitance from being generated even when the second extraction electrode 11B1 and the second wiring line 32 are arranged so as to overlap each other in the plan view. Further, on the base substrate 30A, it is possible to arrange the second wiring line 32 in a space limited in area.

As described above, in a resonator device 100A according to the modified example, it is preferable for the resonator element 12 to be provided with the first extraction electrode 11A1 coupled to the first excitation electrode 11A, and it is preferable for the first extraction electrode 11A1 to be arranged at the position overlapping the first wiring line 31 in the plan view. According to this configuration, the first extraction electrode 11A1 is an electrode which is electrically coupled to the first excitation electrode 11A, and has the same potential as that of the first excitation electrode 11A similarly to the first wiring line 31. Therefore, it is possible to prevent the parasitic capacitance from being generated even when the first extraction electrode 11A1 and the first wiring line 31 are arranged so as to overlap each other in the plan view. Further, on the base substrate 30A, it is possible to arrange the first wiring line 31 in a space limited in area.

As described above, in the resonator device 100A according to the modified example, it is preferable for the resonator element 12 to be provided with the second extraction electrode 11B1 coupled to the second excitation electrode 11B, and it is preferable for the second wiring line 32 to be arranged at the position overlapping the second extraction electrode 11B1 in the plan view. According to this configuration, the second extraction electrode 11B1 is an electrode which is electrically coupled to the second excitation electrode 11B, and has the same potential as that of the second excitation electrode 11B similarly to the second wiring line 32. Therefore, it is possible to prevent the parasitic capacitance from being generated even when the second extraction electrode 11B1 and the second wiring line 32 are arranged so as to overlap each other in the plan view. Further, on the base substrate 30A, it is possible to arrange the second wiring line 32 in a space limited in area.

Further, as described above, arranging the semiconductor element 40 on the base substrate 30 having the recessed part is not a limitation, and it is possible to arrange the semiconductor element on the lid substrate 20 having the recessed part.

Further, as described above, the first wiring line 31 is not limited to being arranged so as not to overlap the second excitation electrode 11B in the plan view, and it is possible to arrange the first wiring line 31 so as not to overlap the resonator element 12 in the plan view. In this way, it becomes possible to increase the distance between the first wiring line 31 and the second excitation electrode 11B in the plan view, and it is possible to further prevent the parasitic capacitance from being generated. It should be noted that the same applies to the second wiring line 32.

As described hereinabove, in the resonator device according to the modified example, it is preferable for the first wiring line 31 to be arranged at the position not overlapping the resonator element 12 in the plan view. According to this configuration, since the first wiring line 31 is arranged so as not to overlap the resonator element 12, it becomes possible to ensure the distance between the first wiring line 31 and the second excitation electrode 11B, and thus, it is possible to prevent the parasitic capacitance from being generated between the wiring lines coupled to the resonator element 12. It should be noted that it is preferable to adopt substantially the same arrangement with respect to the second wiring line 32.

What is claimed is:

1. A resonator device comprising:
an element substrate having a resonator element which has a first excitation electrode arranged on one surface and a second excitation electrode arranged on another surface, and a frame surrounding the resonator element;
a first substrate bonded to one surface of the frame;
a second substrate bonded to another surface of the frame; and
a semiconductor element including an oscillation circuit electrically coupled to the resonator element, wherein
the frame, the first substrate, and the second substrate form a cavity configured to house the resonator element and the semiconductor element,
the second substrate includes a first wiring line which is arranged on a surface faced to the second excitation electrode, and which is configured to electrically couple the first excitation electrode and the semiconductor element to each other, and
the first wiring line is arranged at a position which fails to overlap the second excitation electrode in a plan view.

2. The resonator device according to claim 1, wherein
the resonator element is provided with a second extraction electrode coupled to the second excitation electrode, and
the first wiring line is arranged at a position which fails to overlap the second excitation electrode and the second extraction electrode in the plan view.

3. The resonator device according to claim 1, wherein
the second substrate includes a second wiring line which is arranged on a surface faced to the second excitation electrode, and which is configured to electrically couple the second excitation electrode and the semiconductor element to each other,
the first wiring line is arranged at one side of the base substrate, and
the second wiring line is arranged at another side as an opposite direction to the one side of the second substrate.

4. The resonator device according to claim 1, wherein
the resonator element is provided with a first extraction electrode coupled to the first excitation electrode, and
the first extraction electrode is arranged at a position which overlaps the first wiring line in the plan view.

5. The resonator device according to claim 2, wherein
the second substrate includes a second wiring line which is arranged on a surface faced to the second excitation electrode, and which is configured to electrically couple the second excitation electrode and the semiconductor element to each other, and
the second wiring line is arranged at a position which overlaps the second extraction electrode in the plan view.

6. The resonator device according to claim 1, wherein
the first wiring line is arranged at a position which fails to overlap the resonator element in the plan view.
